(19) United States
(12) Patent Application Publication
(10) Pub. No.: US 2013/0208545 A1
(43) Pub. Date: Aug. 15, 2013

(54) SEMICONDUCTOR MEMORY APPARATUS, PROGRAM METHOD THEREOF, AND DATA PROCESSING SYSTEM USING THE SAME

(71) Applicant: Jae Ho LEE, Icheon-si (KR)

(72) Inventor: Jae Ho LEE, Icheon-si (KR)

(73) Assignee: SK HYNIX INC., Icheon-si (KR)

(21) Appl. No.: 13/604,116

(22) Filed: Sep. 5, 2012

(30) Foreign Application Priority Data
Feb. 9, 2012 (KR) 10-2012-0013246

(51) Int. Cl. G11C 16/12; G11C 16/04

(52) U.S. Cl. 365/185.23

(57) ABSTRACT

A semiconductor memory apparatus includes: a memory cell area including a plurality of memory cells each coupled between a word line and a bit line; and a controller configured to set a word line voltage and a bit line voltage at the same time, in response to a program command.

### CROSS-REFERENCES TO RELATED APPLICATION

The present application claims priority under 35 U.S.C. §119(a) to Korean application number 10-2012-0013246, filed on Feb. 9, 2012, in the Korean Intellectual Property Office, which is incorporated herein by reference in its entirety.

### BACKGROUND

1. Technical Field

The present invention relates generally to a memory system, and more particularly to a semiconductor memory apparatus, a program method thereof, and a data processing system using the same.

2. Related Art

A semiconductor memory apparatus such as a flash memory apparatus is a memory apparatus capable of replacing a hard disk drive (HDD) which is an existing large-capacity storage device. The semiconductor memory apparatus has small power consumption, is shock-resistant, and may be configured with a high capacity and a high integration degree.

### SUMMARY

In an embodiment of the present invention, a semiconductor memory apparatus includes: a memory cell area including a plurality of memory cells each connected between a word line and a bit line; and a controller configured to set a word line voltage and a bit line voltage at the same time, in response to a program command.

In an embodiment of the present invention, a program method of a semiconductor memory apparatus which includes a controller to control a memory cell area includes the steps of: setting, by the controller, all memory cells of the memory cell area to a program-inhibited state in response to a program command; boosting a channel of the memory cell; stabilizing a word line voltage and a bit line voltage connected to the memory cell area; and changing a channel voltage of the memory cell.

In an embodiment of the present invention, a data processing system includes: a host apparatus; and a semiconductor memory apparatus connected to the host apparatus through a host interface, wherein the semiconductor memory apparatus includes a controller configured to set a word line voltage and a bit line voltage of a memory area at the same time, in response to a program command.

In an embodiment of the present invention, a semiconductor memory apparatus includes: a memory cell area connected in series between a drain select switch and a source select switch which are connected to a bit line, and including a plurality of strings each having a plurality of memory cells each of which has a gate terminal connected to a word line; a block switch configured to drive the drain select switch; a voltage provider configured to generate a high voltage depending on each operation mode of the semiconductor memory apparatus and provide the generated high voltage to the word line; and a controller configured to supply a predetermined level of voltage to the word line and the bit line through the voltage provider while controlling on/off of the drain select switch through the block switch, and stabilize the word line voltage and the bit line voltage to predetermined levels at the same time, in response to a program command.

### BRIEF DESCRIPTION OF THE DRAWINGS

Features, aspects, and embodiments are described in conjunction with the attached drawings, in which:

FIG. 1 is a diagram for explaining a memory cell array structure of a semiconductor memory device according to an embodiment of the present invention;

FIG. 2 is a diagram for explaining the position tendency of memory cells in a semiconductor memory apparatus;

FIG. 3 is a diagram for explaining an effect of coupling capacitance between bit lines;

FIGS. 4 and 5 are diagrams for explaining a method for setting a bit line voltage in a memory apparatus according to an embodiment of the present invention;

FIG. 6 is a timing diagram for explaining a program method according to an embodiment of the present invention;

FIG. 7 is a timing diagram for explaining an example of the program method of a semiconductor memory apparatus according to an embodiment of the present invention;

FIG. 8 is a configuration diagram of a semiconductor memory apparatus according to an embodiment of the present invention;

FIG. 9 is a flow chart for explaining a program method according to an embodiment of the present invention;

FIG. 10 is a timing diagram for explaining the program method according to an embodiment of the present invention; and

FIG. 11 is a configuration diagram of a data processing system according an embodiment of the present invention.

### DETAILED DESCRIPTION

Hereinafter, a semiconductor memory apparatus, a program method thereof, and a data processing system using the same according to the present invention will be described below with reference to the accompanying drawings through exemplary embodiments.

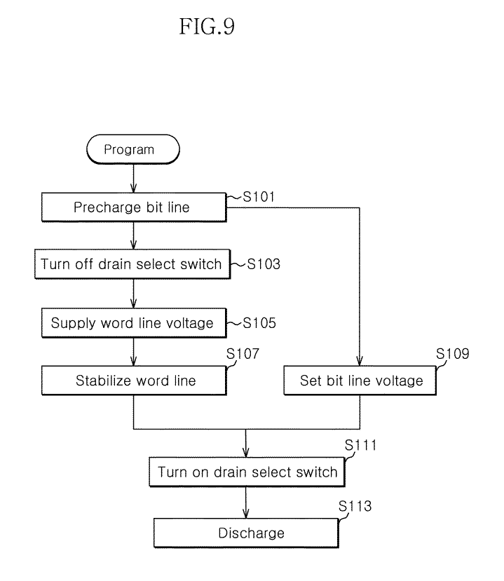

FIG. 8 is a configuration diagram of a semiconductor memory apparatus according to an embodiment of the present invention.

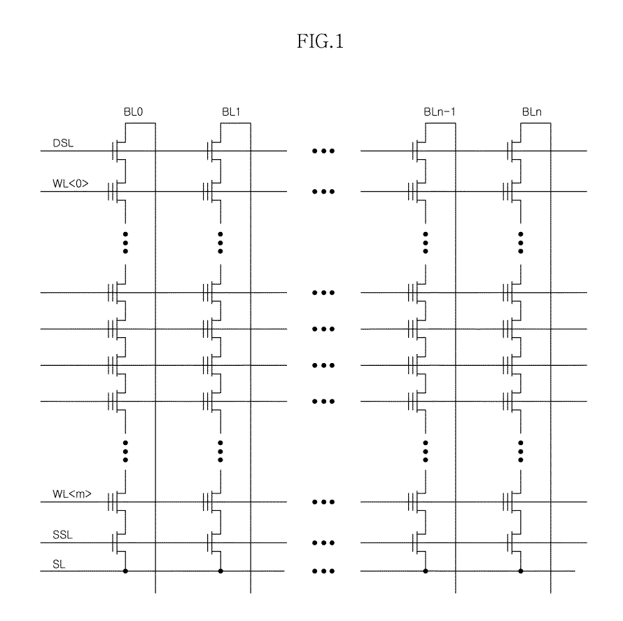

FIG. 1 is a diagram for explaining a memory cell array structure of a semiconductor memory device according to an embodiment of the present invention.

Referring to FIG. 1, the memory cell array may have a string structure. For example, memory cells each coupled to a word line WL form a string, and each string is coupled to a bit line BL. That is, a plurality of memory cells are connected in series to a drain select switch driven by a voltage applied to a drain select line DSL, thereby forming a string, and the final cell of the string is connected to a source select switch driven by a voltage applied to a source select line SSL. Furthermore, a plurality of memory cells connected to a word line WL form a page.

If the semiconductor memory apparatus is a NAND flash memory apparatus, a program operation is performed on a page basis. The program operation refers to an operation of storing electrons in a floating gate of a memory cell using a FN tunneling effect based on an electric field difference between a channel and the floating gate of the memory cell. For this operation, a control gate voltage may be controlled by transferring a voltage to a word line, and a channel voltage may be controlled by adjusting a bit line voltage. The memory cell has a separate channel, and channel voltages of a cell selected for programming and a program-inhibited cell are controlled through a bit line.

When a program command is applied, a bit line voltage is set, and a high voltage generated by a voltage provider is applied to a selected word line of a program-target block. The bit line voltage serves as a reference voltage for deciding whether or not to program a memory cell.

When a high voltage is applied to a word line to perform a program operation, the high voltage generated by the voltage provider is transmitted to a local word line through a block switch and a global word line. This process will be described in more detail as follows.

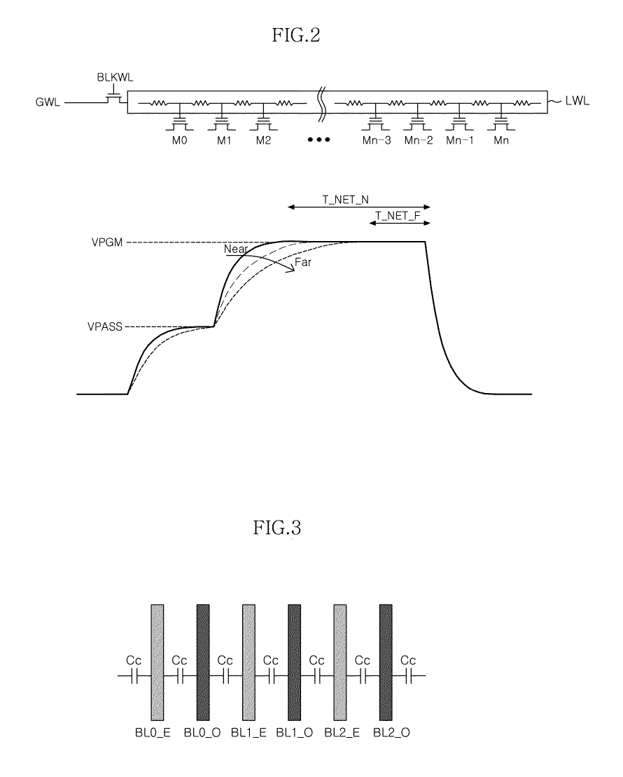

FIG. 2 is a diagram for explaining the position tendency of memory cells in a semiconductor memory apparatus.

Referring to FIG. 2, a high voltage applied to a global word line GWL is applied to a local word line LWL through a block switch driven by a block select signal BLKWL. FIG. 2 emphasizes the local word line LWL.

However, resistors and capacitors exist between memory cells M0 to Mn connected to the local word line LWL, respectively, thereby causing transmission delay of a word line voltage.

Therefore, the magnitudes of voltages transmitted to a memory cell near a row decoder and a memory cell far from the row decoder, respectively, have different values depending on the time.

Referring to a graph of FIG. 2, it can be seen that a short time is required until the memory cell near the row decoder approaches a pass voltage VPASS and then approaches a program voltage VPGM. On the other hand, a long time is required until the memory cell far from the row decoder approaches the pass voltage VPASS or the program voltage VPGM.

After the word line voltage approaches the program voltage VPGM, a predetermined stabilization time T_NET is needed. Therefore, a stabilization time T_NET_N of a word line which approaches the program voltage VPGM at an earlier time may vary depending on a stabilization time T_NET_F of a word line which approaches the program voltage VPGM at a later time.

That is, due to the position tendency of memory cells connected to a word line, a difference occurs in the characteristic between cells and the voltage distribution. Such a difference makes it difficult to shorten the time required for stabilizing the program voltage.

In addition, the semiconductor memory apparatus sets a bit line voltage before supplying a word line voltage during a program operation. Between adjacent bit lines, coupling capacitance exists depending on a distance therebetween. The coupling capacitance serves as a factor to decide a bit line voltage setting time.

FIG. 3 is a diagram for explaining an effect of coupling capacitance between bit lines.

Referring to FIG. 3, it can be seen that a coupling capacitor Cc exists between adjacent bit lines. As a semiconductor memory apparatus is configured with a high capacity and a high integration degree, a distance between bit lines decreases. Accordingly, the magnitude of the coupling capacitance increases. Recently, research has been conducted on various methods for excluding an effect caused by coupling capacitance and setting a bit line voltage at high speed.

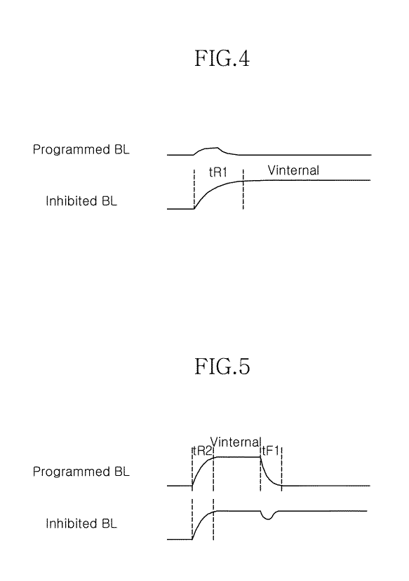

FIGS. 4 and 5 are diagrams for explaining a method for setting a bit line voltage in a memory apparatus.

FIG. 4 illustrates a case in which only a bit line of a program-inhibited cell is precharged to an internal voltage Vinternal. In this case, since coupling capacitance between bit lines acts as it is, a lot of time is required (tR1) until the voltage of the bit line rises to the internal voltage Vinternal.

FIG. 5 illustrates a case in which a bit line of a cell selected for programming and a bit line of a program-inhibited cell are precharged at the same time, and the bit line of the cell selected for programming is discharged to 0V when the voltage of the bit line rises to the internal voltage Vinternal.

In this case, since an effect caused by coupling capacitance between bit lines may be removed, the bit lines may be quickly precharged (tR2). However, a time (tF1) may be required for discharging the bit line of the cell selected for programming and a time may also be required for stabilizing the precharged bit line.

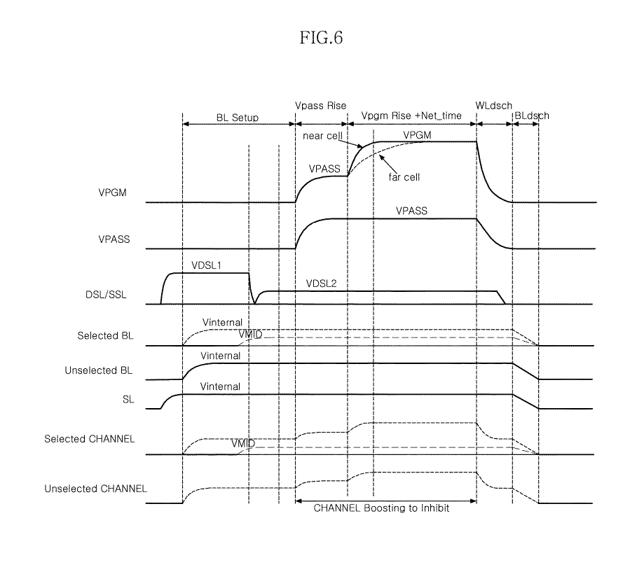

FIG. 6 is a timing diagram for explaining a program method according to an embodiment of the present invention, illustrating the program method when the bit line voltage setting method described with reference to FIG. 4 is applied.

The drain select switch and the source select switch are turned on to apply a first power supply voltage (for example, 5V) to the drain select line DSL and the source select line SSL.

Then, a bit line voltage is set. An unselected bit line and a program-inhibited bit line of a selected bit line are precharged to the internal voltage Vinternal, and a middle voltage VMID or ground voltage (0V) is applied to the selected bit line. When the selected bit line is set to the middle voltage VMID, a double program method may be applied.

Then, a second power supply voltage (for example, 1.5V) is applied to the drain select line DSL and the source select lien SSL so as to stabilize the bit line voltage.

When the bit line voltage is stabilized, a word line voltage is supplied. The program voltage VPGM is supplied to a word line of the cell selected for programming, and the pass voltage VPASS is supplied to a word line of the program-inhibited cell. After the voltages of all word lines rise to the pass voltage level VPASS, the word line voltage of the cell selected for programming rises to the program voltage VPGM.

In this case, the word line voltage of a memory cell near the row decoder rises to the program voltage VPGM at high speed (near cell), and the word line voltage of a memory cell far from the row decoder rises to the program voltage VPGM at low speed (far cell). Until the program voltage VPGM is applied to control gates of all memory cells connected to the selected word line, a predetermined stabilization time NET time is need.

The bit line of the cell selected for programming maintains the ground voltage or the middle voltage. Furthermore, as the drain select switch is turned off, the connection between the channel of the program-inhibited cell and the bit line is cut off, and the program-inhibited cell becomes in a floating state. Furthermore, as the word line voltage increases, channel boosting occurs due to a coupling effect, thereby causing a high-voltage state. Accordingly, as an electric field difference between the word line and the channel decreases, a program operation is not performed.

After the word line voltage is stabilized, the word line and the bit lines are discharged.

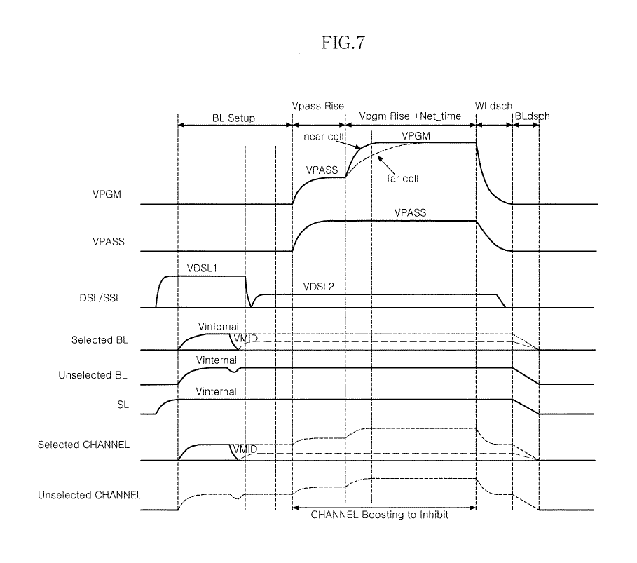

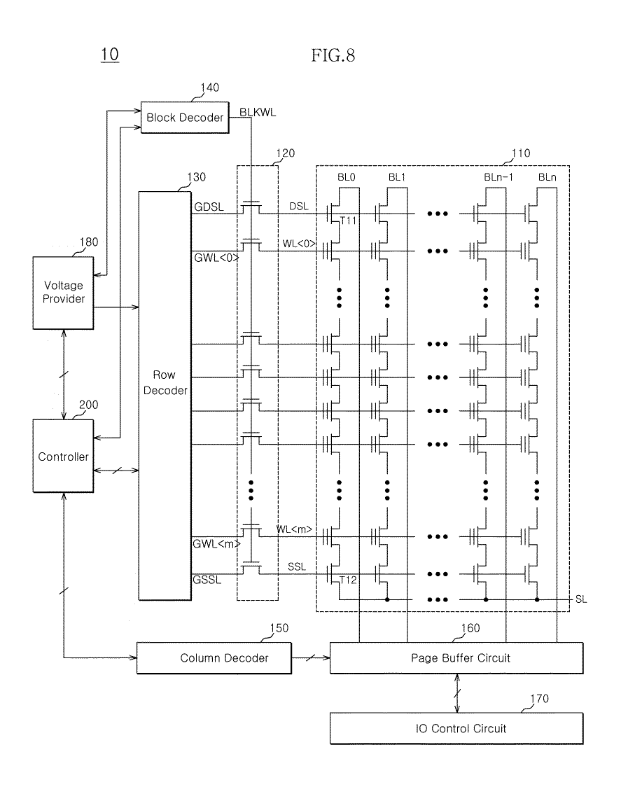

FIG. 7 is a timing diagram for explaining another example of the program method of a semiconductor memory apparatus according to an embodiment of the present invention, illustrating the program method when the bit line voltage setting method described with reference to FIG. 5 is applied.

The program method of FIG. 7 is similar to that of FIG. 6, but has a difference in the bit line voltage setting method.

That is, after a first power supply voltage (for example, 5V) is applied to the drain select line DSL and the source select line SSL, bit line voltages are set. After all bit lines are precharged to internal voltage Vinternal, a bit line of a cell selected for programming is discharged to the middle voltage VMID or ground voltage (0V).

Then, when the bit lines are stabilized, a word line voltage is supplied, and when the word line voltage is stabilized, the word line and the bit lines are discharged.

As known from FIGS. 6 and 7, the semiconductor memory apparatus supplies the word line voltage after the bit line voltages are stabilized during the program operation. Then, after the word line voltage is stabilized, the word line and the bit lines are discharged.

As described above, a considerable time is required until the bit line voltage is stabilized to a desired level, due to the coupling capacitance between bit lines. Furthermore, since the word line voltage must be supplied and stabilized after the corresponding time passes, the entire program time inevitably increases.

Furthermore, due to the position tendency of memory cells connected to a word line, a time is required until a control gate of a memory cell far from the row decoder is stabilized to a desired level. As a result, the time required for setting the bit line voltage increases during the program operation of the semiconductor memory apparatus. Furthermore, since the bit line voltage and the word line voltage are set at different times, the entire program time may increase.

Recently, word lines and bit lines have been gradually reduced in size and increased in length, for high integration of semiconductor memory apparatuses. Such a trend may cause the position tendency of memory cells connected to a word line, and the time required for a program operation may further increase due to an effect of coupling capacitance between bit lines.

Referring to FIG. 8, the semiconductor memory apparatus 10 according to an embodiment of the present invention includes a memory cell area 110, a block switch 120, a row decoder 130, a block decoder 140, a column decoder 150, a page buffer circuit 160, an IO control circuit 170, a voltage provider 180, and a controller 200.

The memory cell area 110 may include one or more planes each including one or more banks. For example, the memory cell area 110 may be configured using flash memory cells. Furthermore, each of the memory cells is coupled between a word line and a bit line, and a drain select switch T11 and a source select switch T12 are provided at both sides of each string. The drain select switch T11 is driven by a voltage applied to a drain select line DSL, and the source select switch T12 is driven by a voltage applied to a source select line SSL. Furthermore, memory cells coupled to a word line WL may form a page.

The block switch 120 is configured to apply a high voltage generated by the voltage provider 180 to the memory cell area 110 according to the level of a block select signal BLKWL outputted from the block decoder 140. For this operation, the block switch 120 includes switches for connecting global word lines GWL to the memory cell area 110 and switches for connecting a global drain select line GDSL and a global source select line GSSL to the memory cell area 110.

The row decoder 130 is configured to decode a word line address for accessing the memory cell area 110, based on a row address provided from outside. The block decoder 140 is configured to decode a block address signal and generate the block select signal BLKWL to control the block switch 120. Furthermore, the column decoder 150 decodes a bit line address to be accessed, based on a column address signal provided from outside.

The page buffer circuit 160 is coupled to a bit line extended from the memory cell area 110. Furthermore, the page buffer circuit 160 operates according to the decoding result of the column decoder 150, and transmits and receives data to and from the IO control circuit unit 170.

The voltage provider 180 includes one or more pumps and is configured to provide a high voltage for each operation mode of the semiconductor memory apparatus 10. Furthermore, the high voltage generated by the voltage provider 180 is provided to the block switch 120 through the row decoder 130. As the block switch 120 is turned on by the block decoder 140, the high voltage is applied to a selected block of the memory cell area 110.

The controller 200 is configured to receive an external control signal, a command signal, and external address signals, and generate an internal command signal corresponding to the command signal. Furthermore, the controller 200 generates internal addresses based on the external address signals, and provides the generated internal addresses to the respective decoders 130, 140, and 150.

As a program command is provided, the controller 200 generates an internal program command to control the voltage provider 180 and the decoders 130, 140, and 150.

FIG. 9 is a flow chart for explaining a program method according to an embodiment of the present invention.

The controller 200 precharges all bit lines to an internal voltage Vinternal in a state where the drain select switch T11 is turned on according to a program command, at step S101. Then, the drain select switch T11 is turned off to set all memory cells in the same state as a program-inhibited cell, at step S103.

In this state, a word line voltage is supplied at step S105. Then, channels of all the memory cells are boosted into a high voltage state. Furthermore, while the word line is stabilized at step S107, bit line voltages are set at step S109.

The bit line voltages may be set as follows: an unselected bit line and a bit line coupled to a program-inhibited cell are set to the internal voltage Vinternal, and a bit line coupled to a cell selected for programming is set to a middle voltage VMID (in the case of double program) or ground voltage (0V).

After the word line voltage and the bit line voltages are stabilized, the drain select switch T11 is turned on at step S111. Here, since each of the bit line has a voltage level depending on whether the corresponding memory cell is programmed or not and has a different voltage level from each other, the bit line voltage is equalized to a channel voltage by charge-sharing between the bit line and the channel. Furthermore, since a difference between bit line capacitance and channel capacitance is large (bit line capacitance>>channel capacitance), the channel voltage after charge sharing is equalized to the bit line voltage. Furthermore, since the unselected bit line and the bit line of the program-inhibited cell maintain the internal voltage Vinternal, channels of the corresponding cells maintain a boosting state. Accordingly, FN tunneling does not occur.

After the program operation is completed, the word line and the bit lines are discharged at step S113.

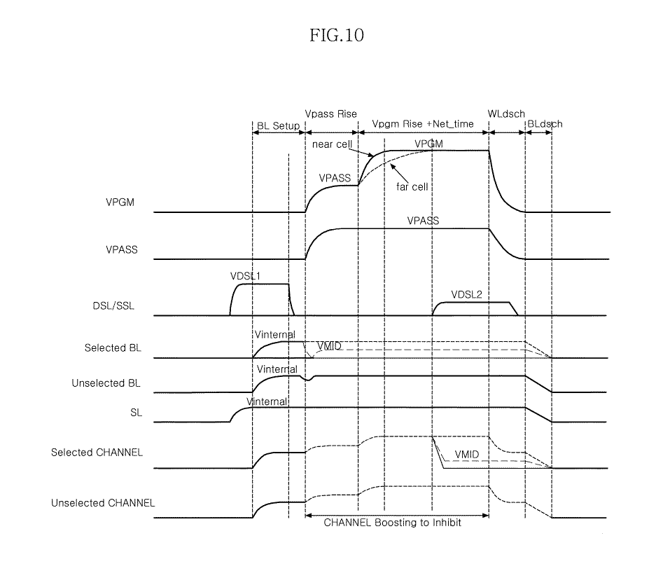

FIG. 10 is a timing diagram for explaining the program method according to an embodiment of the present invention.

After a program command is applied, a first power supply voltage VDSL1 (for example, 5V) is applied to the drain select line DSL to turn on the drain select switch T11. Furthermore, a cell selected for programming and a program-inhibited cell of a selected bit line and an unselected bit line are precharged to the internal voltage level Vinternal (BL setup).

Then, a low-level voltage is applied to the drain select line DSL to turn off the drain select switch T11. Then, all the memory cells are set, for example, in the same state as the program-inhibited cell.

Furthermore, a word line voltage is supplied in a state where the drain select switch T11 is turned off (Vpass Rise). Accordingly, channels of all the memory cells are boosted into a high voltage state. Furthermore, while the word line is stabilized (Vpgm Rise+Net_time), bit line voltages are set and stabilized.

The bit line voltages may be set as follows: an unselected bit line and a bit line of a program-inhibited cell are set to the internal voltage Vinternal, and a bit line of a cell selected for programming is set to a middle voltage VMID (in the case of double program) or ground voltage (0V).

After the word line voltage and the bit line voltages are stabilized, a second power supply voltage VDSL2 (for example, 5V) is applied to the drain select line DSL to turn on the drain select switch T11. The bit line voltage is equalized to a channel voltage by charge-sharing between the bit line and a channel. In particular, since bit line capacitance is much larger than channel capacitance, the channel voltage is equalized to the bit line voltage.

Here, since the unselected bit line and the bit line of the program-inhibited cell maintain the internal voltage Vinternal, the channels of the corresponding cells maintain a boosted state such that program is not performed.

After the program operation is completed, the word line and the bit lines are discharged.

According to an embodiment of the present invention, the word line and the bit line voltages are set in a state where all the bit lines are precharged, and the drain select switch is controlled to reset channel voltages for the unselected bit line and the program-inhibited bit line. Therefore, since the word line voltage and the bit line voltage may be stabilized in the same period, it is possible to shorten the time required for program.

Such a program method may be applied to not only a shielded bit-line structure but also an all bit-line structure.

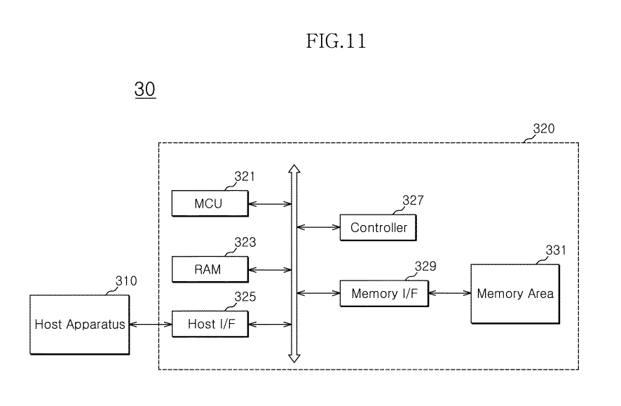

FIG. 11 is a configuration diagram of a data processing system according an embodiment of the present invention.

Referring to FIG. 11, the data processing system 30 according to an embodiment of the present invention includes a host apparatus 310 and a semiconductor memory apparatus 320. The semiconductor memory apparatus 320 may include a micro controller unit (MCU) 321, a working memory (RAM) 323, a host interface 325, a controller 327, a memory interface 329, and a memory area 331.

The MCU 321 is configured to control overall operations of the semiconductor memory apparatus 320, and firmware or applications for the MCU 321 may be loaded into the RAM 323 and then driven.

The RAM 323 may include a device for temporarily storing data required for the operation of the MCU 321. According to the control of the MCU 321, the RAM 323 may temporarily store data of the memory area 331 and then provide the stored data to the host apparatus 310 or may temporarily store data of the host apparatus 310 and then provide the stored data to the memory area 331.

The host interface 325 is configured to control data exchange between the host apparatus 310 and the memory area 331, and provide a protocol conversion function, if necessary.

The controller 327 is coupled to the memory area 331 through the memory interface 329, and configured to provide commands, addresses, control signals, and data to control the operation of the memory area 331. In particular, the controller 327 according to an embodiment of the present invention controls a bit line voltage and a word line voltage to be stabilized at the same time, during a program operation.

More specifically, as a program command is applied, the controller 327 turns on a drain select switch, and then precharges all bit lines to the internal voltage level Vinternal. Then, the controller 327 turns off the drain select switch, and then supplies a word line voltage.

When the word line voltage is supplied, bit line voltages are set in such a manner that an unselected bit line and a program-inhibited bit line maintain the internal voltage level and a selected bit line is set to the middle voltage or ground voltage.

Then, when the drain select switch is turned on again, the unselected bit line and the program-inhibited bit line maintain a boosted state by the word line voltage. In this case, as FN tunneling is prevented, a program operation is not performed. On the other hand, as charge sharing occurs between a channel and the selected bit line, the channel voltage changes to the bit line voltage level.

After the program operation is completed, the word line and the bit lines are discharged.

That is, the controller 327 according to an embodiment of the present invention sets the word line voltage and the bit line voltages in a state where all the bit lines are precharged, and controls the drain select switch to reset the channel voltages for the unselected bit line and the program-inhibited bit line. Therefore, since the word line voltage and the bit line voltage may be stabilized in the same period, it is possible to shorten the time required for program.

Each of memory cell arrays forming the memory area 331 may include a plurality of semiconductor memory cells and may be configured to have one or more plane or one or more chips each including a plurality of banks.

The configuration of the semiconductor memory apparatus 320 is not limited thereto, but devices or components may be added according to the environment of a system to be applied. For example, the semiconductor memory apparatus 320 may further include a ROM for storing data required for an initial booting operation, an error correction unit, a power supply unit, a communication module and the like.

The semiconductor memory apparatus 320 may be packaged into a memory card. Furthermore, the data processing system 30 may further include separate application chipsets, such as a camera module, other than the host 310.

While certain embodiments have been described above, it will be understood to those skilled in the art that the embodiments described are by way of example only. Accordingly, the semiconductor memory apparatus described herein should not be limited based on the described embodiments. Rather, the semiconductor memory apparatus described herein should only be limited in light of the claims that follow when taken in conjunction with the above description and accompanying drawings.

What is claimed is:

1. A semiconductor memory apparatus comprising:
a memory cell area comprising a plurality of memory cells each coupled between a word line and a bit line; and
a controller configured to set a word line voltage and a bit line voltage at the same time, in response to a program command.

2. The semiconductor memory apparatus according to claim 1, wherein the memory cell area comprises a plurality of memory cells coupled in series to a drain select switch, and the controller controls the drain select switch to set the word line voltage and the bit line voltage at the same time.

3. The semiconductor memory apparatus according to claim 1, wherein the word line and the bit line voltages are set in a state where all the bit lines are precharged.

4. The semiconductor memory apparatus according to claim 1, wherein the controller stabilizes the word line voltage and the bit line voltage so as to maintain predetermined levels, respectively, after precharging all bit lines.

5. The semiconductor memory apparatus according to claim 1, wherein the controller sets all the memory cells to a program-inhibited state in response to the program command, and controls channel voltages of memory cells coupled to a program-inhibited bit line and an unselected bit line after stabilizing the word line voltage and the bit line voltage so as to maintain predetermined levels, respectively.

6. A program method of a semiconductor memory apparatus, comprising the steps of:
setting all memory cells of the memory cell area to a program-inhibited state in response to a program command;
boosting a channel of the memory cell;
stabilizing a word line voltage and a bit line voltage coupled to the memory cell area; and
changing a channel voltage of the memory cell.

7. The program method according to claim 6, wherein the memory cell area includes a plurality of memory cells coupled in series to a drain select switch, and
the step of setting all the memory cells of the memory cell area to a program-inhibited state comprises the steps of:
precharging bit lines of all the memory cells in a state where the drain select switch is turned on; and
turning off the drain select switch.

8. The program method according to claim 7, wherein the step of boosting the channel of the memory cell comprises the step of supplying a word line voltage.

9. The program method according to claim 7, wherein the step of stabilizing the word line voltage and the bit line voltage comprises the step of controlling bit line voltages of an unselected bit line and a program-inhibited bit line to maintain the precharged state, and changing a voltage level of a bit line, coupled to a target cell of a program operation, to a designated level.

10. The program method according to claim 7, wherein the step of changing the channel voltage comprises the step of turning on the drain select switch.

11. A data processing system comprising:
a host apparatus;
a semiconductor memory apparatus coupled to the host apparatus through a host interface; and
a controller configured to set a word line voltage and a bit line voltage of a memory area at the same time, in response to a program command.

12. The data processing system according to claim 11, wherein the controller is arranged in the semiconductor memory apparatus.

13. The data processing system according to claim 11, wherein the controller stabilizes the word line voltage and the bit line voltage to predetermined levels, respectively, after precharging all bit lines.

14. The data processing system according to claim 11, wherein the controller sets all memory cells of the memory area to a program-inhibited state in response to the program command, and controls channel voltages of memory cells coupled to a program-inhibited bit line and an unselected bit line after stabilizing the word line voltage and the bit line voltage to predetermined levels, respectively.

15. A semiconductor memory apparatus comprising:
a memory cell area coupled in series between a drain select switch and a source select switch which are coupled to a bit line, and comprising a plurality of strings each having a plurality of memory cells each of which has a gate terminal coupled to a word line;
a block switch configured to drive the drain select switch;
a voltage provider configured to generate a high voltage depending on each operation mode of the semiconductor memory apparatus and provide the generated high voltage to the word line; and
a controller configured to supply a predetermined level of voltage to the word line and the bit line through the voltage provider while controlling on/off of the drain select switch through the block switch, and stabilize the word line voltage and the bit line voltage to predetermined levels at the same time, in response to a program command.

16. The semiconductor memory apparatus according to claim 15, wherein the controller stabilizes the word line voltage and the bit line voltage to predetermined levels, respectively, after precharging all bit lines.

17. The semiconductor memory apparatus according to claim 15, wherein the controller sets all memory cells to a program-inhibited state by turning off the drain select switch after precharging bit lines of all the memory cells in a state where the drain select switch is turned on, in response to the program command, and
when a channel of the memory cell is boosted, the controller controls channel voltages of memory cells coupled to a program-inhibited bit line and an unselected bit line after stabilizing the word line voltage and the bit line voltage to predetermined levels, respectively.

18. The semiconductor memory apparatus according to claim 17, wherein the controller applies a word line voltage to boost the channel of the memory cell, after setting all the memory cells to a program-inhibited state.

19. The semiconductor memory apparatus according to claim 17, wherein the controller maintains bit line voltages of the unselected bit line and the program-inhibited cell to the precharged state, and changes a voltage level of a bit line, coupled to a target cell of a program operation, to a designated level so as to stabilize the bit line voltage.

20. The semiconductor memory apparatus according to claim 17, wherein the controller turns on the drain select switch to change the channel voltage.
